(19) United States
(12) Patent Application Publication
(10) Pub. No.: US 2007/0284089 A1
(43) Pub. Date: Dec. 13, 2007

(54) Method, apparatus and system for carbon nanotube wick structures

(75) Inventors: Unnikrishnan Vadakkanmaruveedu, Portland, OR (US); Gregory M. Chrysler, Chandler, AZ (US); Ravi S. Prasher, Phoenix, AZ (US); Himanshu Pokharna, Santa Clara, CA (US)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/444,739

(22) Filed: May 31, 2006

(51) Int. Cl. H05K 7/20

(52) U.S. Cl. 165/104.26; 165/104.33; 361/700

(57) ABSTRACT

A method, apparatus and system are described for carbon nanotube wick structures. The system may include a frame and an apparatus. The apparatus may include a heat exchanger, a cold plate with a cold plate internal volume, and a heat pipe in the cold plate internal volume. In some embodiments, the heat pipe includes a thermally conductive wall material forming the inner dimensions of the heat pipe, a catalyst layer deposited onto the wall material, a carbon nanotube array formed on the catalyst layer, and a volume of working fluid. Other embodiments may be described.

### BACKGROUND

1. Technical Field

Some embodiments of the present invention generally relate to cooling systems. More specifically, some embodiments relate to use of carbon nanotube wick structures in cooling systems.

2. Discussion

Heat pipes are used with other components to remove heat from structures such as an integrated circuit (IC). An IC die is often fabricated into a microelectronic device such as a processor. The increasing power consumption of processors results in tighter thermal budgets for a thermal solution design when the processor is employed in the field. Accordingly, a thermal or cooling solution is often needed to allow the heat pipe to more efficiently transfer heat from the IC.

Various techniques have been employed to transfer heat away from an IC. These techniques include passive and active configurations. One passive configuration involves a conductive material in thermal contact with the IC.

### BRIEF DESCRIPTION OF THE DRAWINGS

Various advantages of embodiments of the present invention will become apparent to one of ordinary skill in the art by reading the following specification and appended claims, and by referencing the following drawings, in which:

FIG. 1 is a cross-section of a heat pipe according to some embodiments of the system;

FIG. 2 is a cross-section of a heat pipe according to some embodiments of the invention;

FIG. 3 is a schematic diagram of a carbon nanotube forming process according to some embodiments of the invention;

FIG. 4 is a schematic diagram of an apparatus according to some embodiments of the invention;

FIG. 5 includes a schematic diagram of a computer system according to some embodiments of the invention;

FIG. 6 includes a schematic diagram of a computer system according to some embodiments of the invention; and

FIG. 7 includes a flowchart of the process for forming carbon nanotube wick structures in a heat pipe or vapor chamber according to some embodiments of the invention.

### DETAILED DESCRIPTION OF SOME EMBODIMENTS

Reference is made to some embodiments of the invention, examples of which are illustrated in the accompanying drawings. While the present invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims. Moreover, in the following detailed description of the invention, numerous specific details are set forth in order to provide a thorough understanding of the invention. However, the invention may be practiced without these specific details. In other instances, well-known methods, procedures, components and circuits have not been described in detail as not to unnecessarily obscure aspects of the invention.

Reference in the specification to “some embodiments” or “some embodiments” of the invention means that a particular feature, structure or characteristic described in connection with the embodiment is included in at least some embodiments of the invention. Thus, the appearances of the phrase “in some embodiments” or “according to some embodiments” appearing in various places throughout the specification are not necessarily all referring to the same embodiment.

In some embodiments, a heat pipe or vapor chamber includes carbon nanotube wick structures to facilitate the transfer of thermal energy. The heat pipe may be implemented within an apparatus with a heat exchanger, and a cold plate with a cold plate internal volume. In some embodiments, the heat pipe may be situated within the cold plate internal volume. In some embodiments, the heat pipe includes a thermally conductive wall material forming the inner dimensions of the heat pipe, a catalyst layer deposited onto the wall material, a carbon nanotube array formed on the catalyst layer, and a volume of working fluid.

According to some embodiments, the apparatus may be implemented within a computing system. The system may include a frame, one or more electronic components, and the apparatus, which may be implemented to cool one or more of the electronic components.

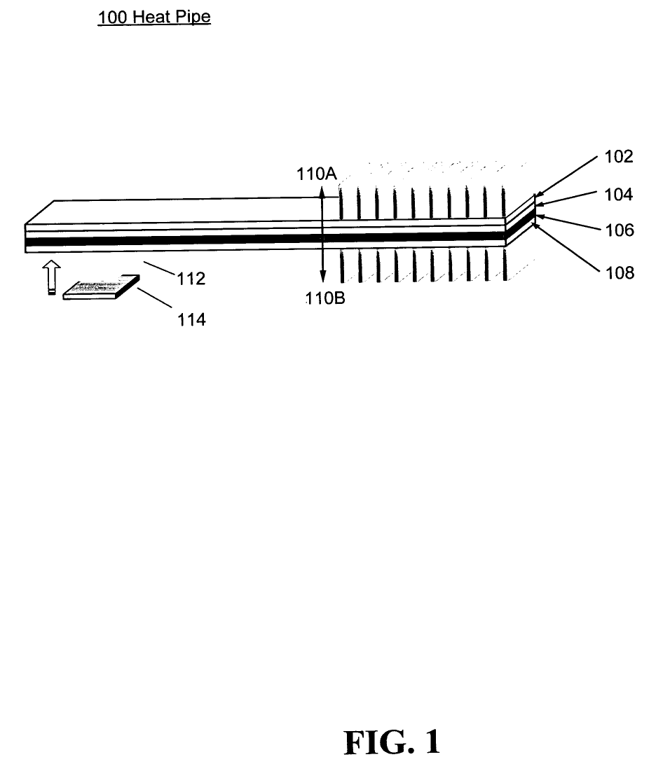

FIG. 1 is a cross-section of a heat pipe according to some embodiments of the system. The heat pipe 100 may use nanotubes of single or multiple wall carbon atoms as a wicking material in the heat pipe. In some embodiments, the heat pipe may be thought of as a vapor chamber. The heat pipe 100 may include a wall material 102/108 to contain the components of the heat pipe. In some embodiments, the wall material 102/108 may include metal, such as but not limited to copper, or silicon. In some embodiments, the wall material 102/108 may be more or less than a millimeter thick.

The heat pipe 100 may also include a wick structure 106, which may in some embodiments be about a millimeter thick. In some embodiments, the wick structure may be formed of carbon nanotubes. The nanotubes are useful due to their thermal properties, as one of ordinary skill in the relevant art would appreciate based at least on the teachings provided herein. As such, the nanotubes may have a thermal conductivity in the range of about 3000 Watts per meter Kelvin. As one of ordinary skill in the relevant art would appreciate, other thermal conductivities may be achieved based on the composition, arrangement and application of the nanotubes.

The heat pipe 100 may also include a vapor space 104, which may in some embodiments be about a millimeter thick. In some embodiments, the vapor space may be filled with a working fluid such as, but not limited to, water or ethanol.

In some embodiments, the wall material 102/108 may be placed in thermal contact with a thermal interface material (TIM) 112, and a die or IC 114. In some embodiments, the heat pipe may include one or more thermally conductive fins 110 on either the top (A) or bottom (B).

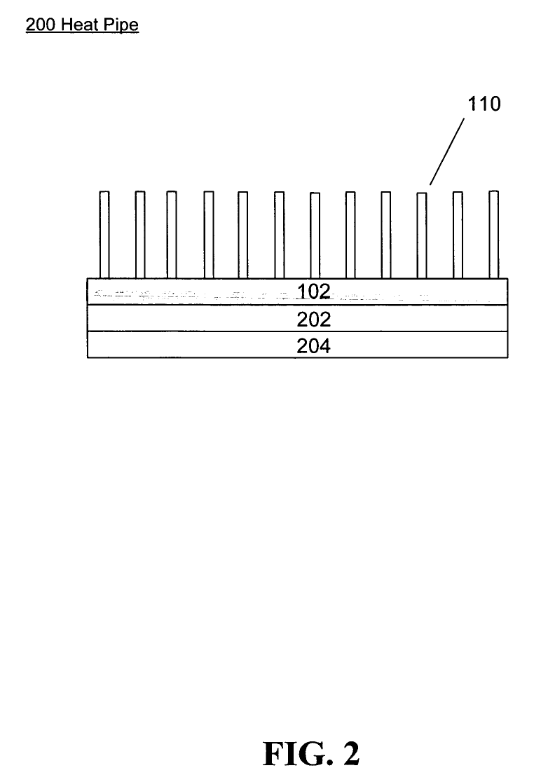

FIG. 2 is a cross-section of a heat pipe 200 according to some embodiments of the invention. The heat pipe may include one or more fins 110 in thermal contact with a wall material 102. A catalyst layer 202 may be formed on the wall material 102. In some embodiments, a wick structure of an array of carbon nanotubes, either single or multiple walled, may be anchored to the catalyst layer 202 by a metal. In some embodiments, the metal may be copper or silicon. Thus, in some embodiments, since the nanotubes 204 may be grown directly on the catalyst layer 202 and may not be attached to any other substrate, the issue of contact resistance may be reduced.

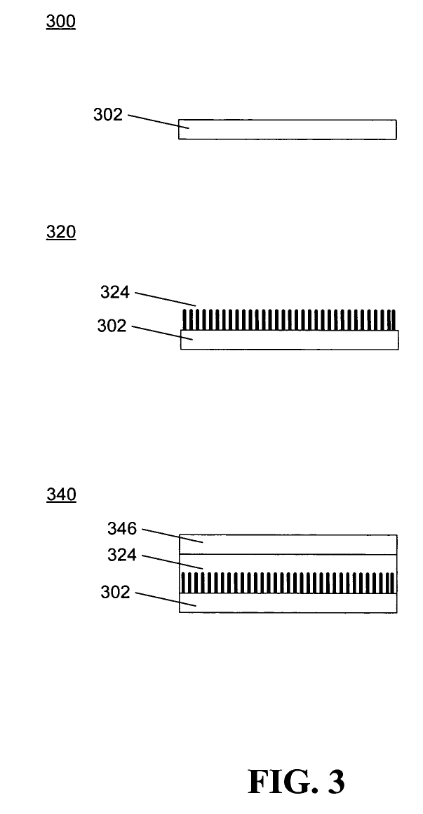

FIG. 3 is a schematic diagram of a carbon nanotube forming process according to some embodiments of the invention. At 300, a heat pipe wall 302 may be placed in a plasma or thermal carbon vapor deposition (CVD) chamber, according to some embodiments. At 320, a plurality of carbon nanotubes 324 may be grown onto over the wall material 302, according to some embodiments of the invention. In some embodiments, the nanotubes may be grown in a relatively vertical orientation, or in a looser orientation growing from the wall material 302. At 340, wall material 346 may be added to form a chamber for the heat pipe that encloses the nanotubes 324. In some embodiments, the nanotubes 324 may form the wick structure when a working fluid is introduced under vacuum and the heat pipe sealed.

Furthermore, the nanotubes may be formed in an array of straight nanotubes grown using plasma CVD, a lithography pattern, or a metalized wall, as one of ordinary skill in the relevant arts would appreciate based at least on the teachings provided herein.

For example, in some embodiments, the nanotubes may be grown using the plasma CVD process or thermal CVD. They may also be grown into arrays or bundles by selective deposition of a catalyst, such as but not limited to nickel, iron, or cobalt, in one or more layers.

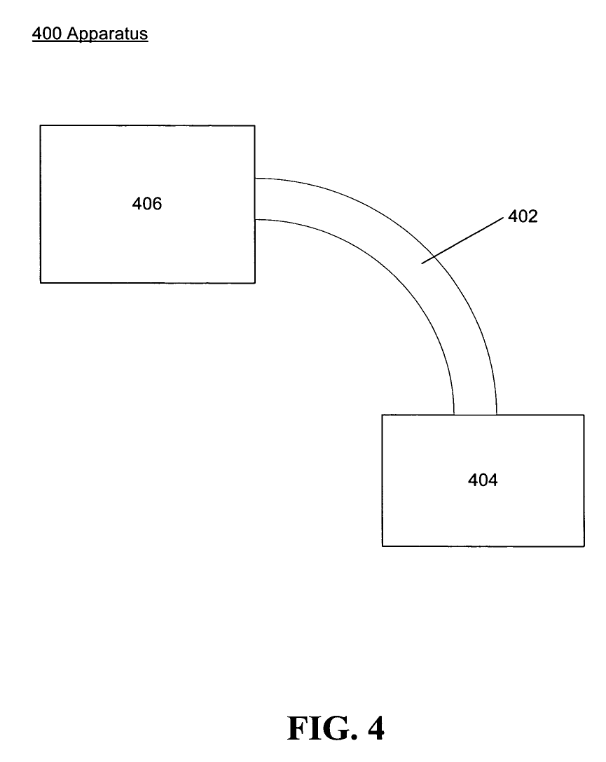

FIG. 4 is a schematic diagram of an apparatus 400 according to some embodiments of the invention. The apparatus 400 may include a heat exchanger 406, a cold plate 404 with a cold plate internal volume, and a heat pipe 402 in the cold plate internal volume. In some embodiments, the heat pipe includes a thermally conductive wall material forming the inner dimensions of the heat pipe, a catalyst layer deposited onto the wall material, a wick of a carbon nanotubes formed on the catalyst layer, and a volume of working fluid.

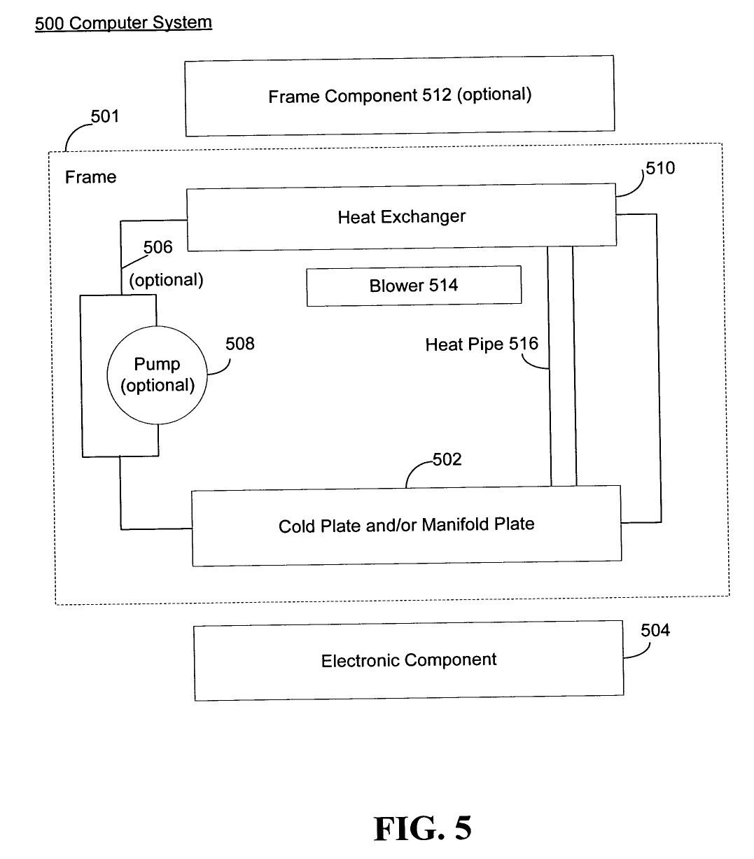

In some embodiments, a conduit of tubing (shown in FIG. 5) may be coupled to the cold plate and the heat exchanger. Furthermore, a pump (shown in FIG. 5) may be coupled to the conduit, wherein the pump may circulate a cooling fluid through the tube between the cold plate and the heat exchanger.

In some embodiments, the cold plate 404 may include a manifold plate, where the manifold plate contains the heat pipe 402.

FIG. 5 includes a schematic diagram of a computer system 500 according to some embodiments of the invention. The computer system 500 may include a frame 501. In some embodiments, the frame 501 may be that of a mobile computer, a desktop computer, a server computer, or a handheld computer. In some embodiments, the frame 501 may be in thermal contact with an electronic component 504. According to some embodiments, the electronic component 504 may include a central processing unit, memory controller, graphics controller, chipset, memory, power supply, power adapter, display, or display graphics accelerator.

The apparatus 400 may be integrated entirely into the frame 501, and thus, the frame 501 may include a heat exchanger 510, a cold plate (or manifold plate) 502 with a cold plate internal volume, and a heat pipe 516 in the cold plate internal volume. In some embodiments, the heat pipe 516 may include a thermally conductive wall material forming the inner dimensions of the heat pipe, a catalyst layer deposited onto the wall material, a wick of a carbon nanotubes formed on the catalyst layer, and a volume of working fluid.

In some embodiments, a conduit of tubing 506 may be coupled to the cold plate 502 and the heat exchanger 510. In some embodiments, a pump 508 may be coupled to the conduit 506, wherein the pump 508 may circulate a cooling fluid through the conduit 506 between the cold plate 502 and the heat exchanger 510.

In some embodiments of the invention, a frame component 512 may be included in the computer system 500. The frame component 512 may receive thermal energy from the heat exchanger 510. The system 500 may also include a blower 514, such as, but not limited to, a fan or other air mover.

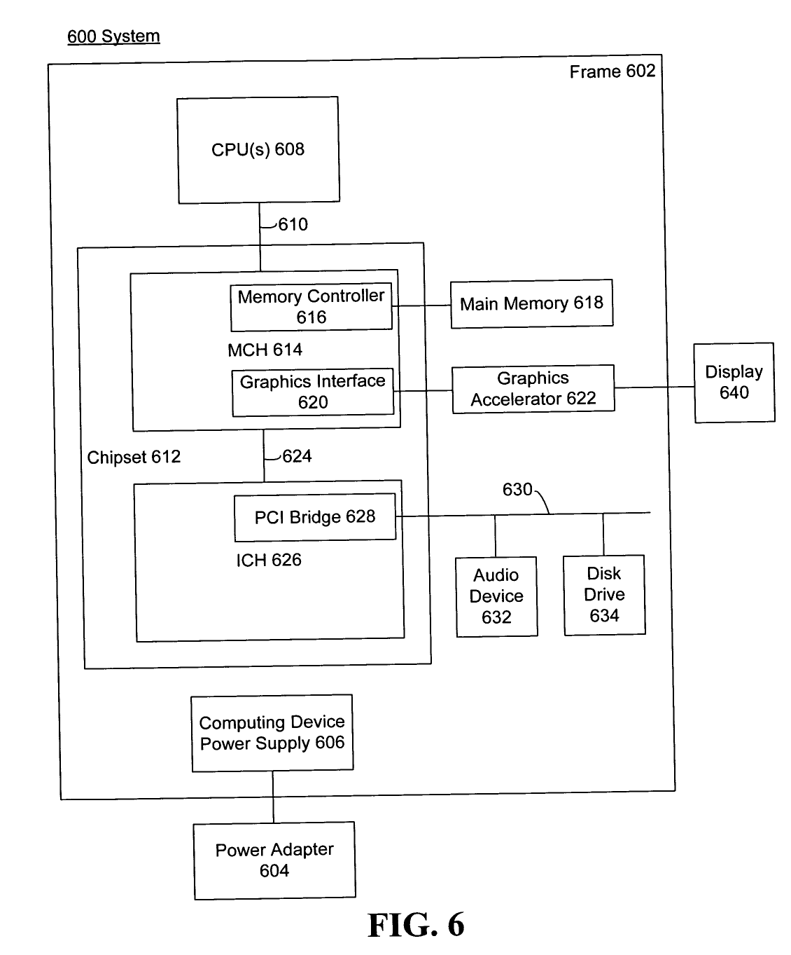

FIG. 6 includes a schematic diagram of a computer system according to some embodiments of the invention. The computer system 600 includes a frame 602 and a power adapter 604 (e.g., to supply electrical power to the computing device 602). The computing device 602 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 602 (e.g., through a computing device power supply 606) from one or more of the following sources: One or more battery packs, an alternating current (AC) outlet (e.g., through a transformer and/or adaptor such as a power adapter 604), automotive power supplies, airplane power supplies, and the like. In some embodiments, the power adapter 604 may transform the power supply source output (e.g., the AC outlet voltage of about 110 VAC to 240 VAC) to a direct current (DC) voltage ranging between about 7 VDC to 12.6 VDC. Accordingly, the power adapter 604 may be an AC/DC adapter.

The computing device 602 may also include one or more central processing unit(s) (CPUs) 608 coupled to a bus 610. In some embodiments, the CPU 608 may be one or more processors in the Pentium® family of processors including the Pentium® II processor family, Pentium® III processors, Pentium® IV processors available from Intel® Corporation of Santa Clara, Calif. Alternatively, other CPUs may be used, such as Intel's Itanium®, XEON™, and Celeron® processors. Also, one or more processors from other manufactures may be utilized. Moreover, the processors may have a single or multiple core design.

A chipset 612 may be coupled to the bus 610. The chipset 612 may include a memory control hub (MCH) 614. The MCH 614 may include a memory controller 616 that is coupled to a main system memory 618. The main system memory 618 stores data and sequences of instructions that are executed by the CPU 608, or any other device included in the system 600. In some embodiments, the main system memory 618 includes random access memory (RAM); however, the main system memory 618 may be implemented using other memory types such as dynamic RAM (DRAM), synchronous DRAM (SDRAM), and the like. Additional devices may also be coupled to the bus 610, such as multiple CPUs and/or multiple system memories.

The MCH 614 may also include a graphics interface 620 coupled to a graphics accelerator 622. In some embodiments, the graphics interface 620 is coupled to the graphics accelerator 622 via an accelerated graphics port (AGP). In an embodiment, a display (such as a flat panel display) 640 may be coupled to the graphics interface 620 through, for example, a signal converter that translates a digital representation of an image stored in a storage device such as video memory or system memory into display signals that are interpreted and displayed by the display. The display 640 signals produced by the display device may pass through various control devices before being interpreted by and subsequently displayed on the display.

A hub interface 624 couples the MCH 614 to an input/output control hub (ICH) 626. The ICH 626 provides an interface to input/output (I/O) devices coupled to the computer system 600. The ICH 626 may be coupled to a peripheral component interconnect (PCI) bus. Hence, the ICH 626 includes a PCI bridge 628 that provides an interface to a PCI bus 630. The PCI bridge 628 provides a data path between the CPU 608 and peripheral devices. Additionally, other types of I/O interconnect topologies may be utilized such as the PCI Express™ architecture, available through Intel® Corporation of Santa Clara, Calif.

The PCI bus 630 may be coupled to an audio device 632 and one or more disk drive(s) 634. Other devices may be coupled to the PCI bus 630. In addition, the CPU 608 and the MCH 614 may be combined to form a single chip. Furthermore, the graphics accelerator 622 may be included within the MCH 614 in other embodiments. As yet another alternative, the MCH 614 and ICH 626 may be integrated into a single component, along with a graphics interface 620.

Additionally, other peripherals coupled to the ICH 626 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 602 may include volatile and/or nonvolatile memory.

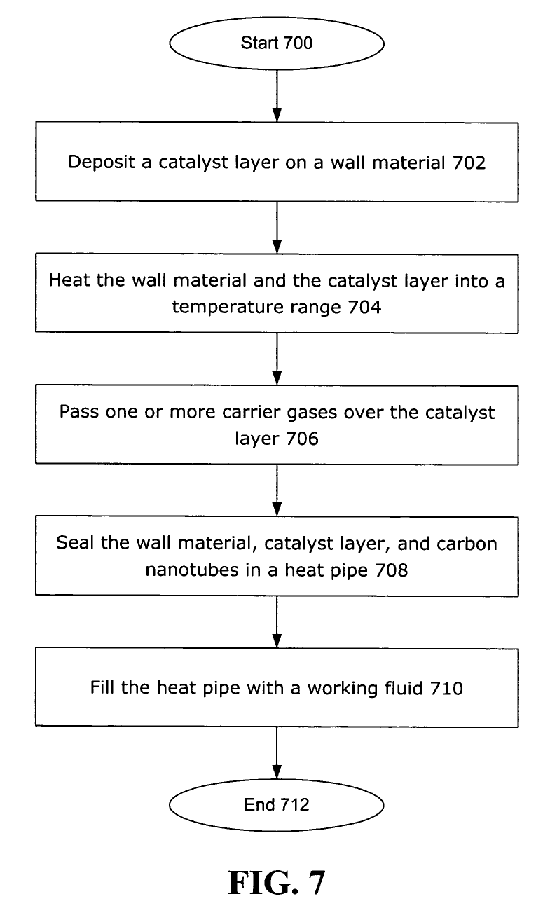

FIG. 7 includes a flowchart of the process for forming carbon nanotube wick structures in a heat pipe or vapor chamber according to some embodiments of the invention. In some embodiments, the process may begin at 700 and proceed immediately to 702, where it may deposit a catalyst layer on a wall material. The process may then proceed to 704, where it may heat the wall material and the catalyst layer into a temperature range. In some embodiments, the temperature range may be around 500-1000 degrees Centigrade for thermal CVD or around 2500-4000 degrees Centigrade for plasma CVD. The process may then proceed to 706, where it may pass one or more carrier gases over the catalyst layer, wherein the passing of the one or more carrier gases over the catalyst layer may result in the growth of carbon nanotubes.

In some embodiments, the process may then proceed to 708, where the process may seal the wall material, catalyst layer, and carbon nanotubes in a heat pipe. The process may then proceed to 710, where it may fill the heat pipe with a working fluid. The process may then proceed to 712 where it ends, and is able to start again at any of the points 700-710, as one of ordinary skill in the relevant arts would appreciate based at least on the teachings provided herein.

Embodiments of the invention may be described in sufficient detail to enable those skilled in the art to practice the invention. Other embodiments may be utilized, and structural, logical, and intellectual changes may be made without departing from the scope of the present invention. Moreover, it is to be understood that various embodiments of the invention, although different, are not necessarily mutually exclusive. For example, a particular feature, structure, or characteristic described in some embodiments may be included within other embodiments. Those skilled in the art can appreciate from the foregoing description that the techniques of the embodiments of the invention can be implemented in a variety of forms.

Therefore, while the embodiments of this invention have been described in connection with particular examples thereof, the true scope of the embodiments of the invention should not be so limited since other modifications will become apparent to the skilled practitioner upon a study of the drawings, specification, and following claims.

What is claimed is:

1. A heat pipe comprising:
a thermally conductive wall material forming the inner dimensions of the heat pipe;
a catalyst layer deposited onto the wall material;
a wick of carbon nanotubes formed on the catalyst layer; and
a volume of working fluid.

2. The heat pipe of claim 1, wherein the wall material includes copper or silicon.

3. The heat pipe of claim 1, wherein the catalyst layer includes metal.

4. The heat pipe of claim 1, wherein the carbon nanotubes are formed using a patterning technique or an evaporation technique.

5. The heat pipe of claim 1, wherein the working fluid is water or ethanol.

6. The heat pipe of claim 1, wherein one or more carrier gases are used to aid in the formation of the carbon nanotubes.

7. The heat pipe of claim 6, wherein the one or more carrier gases are methane or ethylene.

8. An apparatus comprising:
a heat exchanger;
a cold plate with a cold plate internal volume; and
a heat pipe in the cold plate internal volume, wherein the heat pipe includes a thermally conductive wall material forming the inner dimensions of the heat pipe, a catalyst layer deposited onto the wall material, a wick of carbon nanotubes formed on the catalyst layer, and a volume of working fluid.

9. The apparatus of claim 8, further comprising:
a conduit of tubing coupled to the cold plate and the heat exchanger;
a pump coupled to the conduit, wherein the pump circulates a cooling fluid through the tube between the cold plate and the heat exchanger.

10. The apparatus of claim 8, wherein the wall material includes copper or silicon.

11. The apparatus of claim 8, wherein the catalyst layer includes metal.

12. The apparatus of claim 8, wherein the carbon nanotubes are formed using a patterning technique or an evaporation technique.

13. The apparatus of claim 8, wherein the working fluid is water or ethanol.

14. The apparatus of claim 8, wherein one or more carrier gases are used to aid in the formation of the carbon nanotubes.

15. The apparatus of claim 14, wherein the one or more carrier gases are methane or ethylene.

16. The apparatus of claim 8, wherein the cold plate includes a manifold plate, wherein the manifold plate contains the heat pipe.

17. A system comprising:
a frame including an electronic component;
a heat exchanger;
a cold plate with a cold plate internal volume; and
a heat pipe in the cold plate internal volume, wherein the heat pipe includes a thermally conductive wall material forming the inner dimensions of the heat pipe, a catalyst layer deposited onto the wall material, a wick of carbon nanotubes formed on the catalyst layer, and a volume of working fluid.

18. The system of claim 17, further comprising:
a conduit of tubing coupled to the cold plate and the heat exchanger;
a pump coupled to the conduit, wherein the pump circulates a cooling fluid through the conduit between the cold plate and the heat exchanger.

19. The system of claim 17, wherein the wall material includes copper or silicon.

20. The system of claim 17, wherein the catalyst layer includes metal.

21. The system of claim 17, wherein the carbon nanotubes are formed using a patterning technique or an evaporation technique.

22. The system of claim 17, wherein the working fluid is water or ethanol.

23. The system of claim 17, wherein one or more carrier gases are used to aid in the formation of the carbon nanotubes.

24. The system of claim 23, wherein the one or more carrier gases are methane or ethylene.

25. The system of claim 17, wherein the cold plate includes a manifold plate, wherein the manifold plate contains the heat pipe.

26. The system of claim 17, wherein the frame is that of a mobile computer, a desktop computer, a server computer, or a handheld computer.

27. The system of claim 17, further comprising:
a frame component to receive thermal energy from the heat exchanger.

28. The system of claim 17, wherein the electronic component is a central processing unit, memory controller, graphics controller, chipset, memory, power supply, power adapter, display, or display graphics accelerator.

29. A method comprising:
depositing a catalyst layer on a wall material;
heating the wall material and the catalyst layer into a temperature range; and
passing one or more carrier gases over the catalyst layer, wherein the passing of the one or more carrier gases over the catalyst layer results in the growth of carbon nanotubes.

30. The method of claim 29, further comprising:
sealing the wall material, catalyst layer, and carbon nanotubes in a heat pipe; and
filling the heat pipe with a working fluid.

31. The method of claim 29, wherein the depositing is performed using a patterning technique or an evaporation technique.
